(19) United States
(12) Patent Application Publication
(10) Pub. No.: US 2015/0332738 A1
(43) Pub. Date: Nov. 19, 2015

(54) SEMICONDUCTOR MEMORY DEVICE, SEMICONDUCTOR DEVICE INCLUDING THE SAME, AND METHOD FOR OPERATING THE SEMICONDUCTOR DEVICE

(71) Applicant: SK hynix Inc., Gyeonggi-do (KR)

(72) Inventors: Sung-Yub LEE, Gyeonggi-do (KR); Jae-Hoon CHA, Gyeonggi-do (KR)

(21) Appl. No.: 14/543,475

(22) Filed: Nov. 17, 2014

(30) Foreign Application Priority Data
May 19, 2014 (KR) 10-2014-0059707

(51) Int. Cl. G11C 7/02; G11C 7/22; G11C 29/00; G11C 7/10

(52) U.S. Cl. CPC G11C 7/02; G11C 7/1051; G11C 7/22; G11C 29/00

(57) ABSTRACT

A semiconductor device includes: a plurality of internal circuits which receive commands through a plurality of independent command lines in a first operation mode and receive a common command through a common command line in a second operation mode; and an operation control block which duplicates a command applied through a representative independent command line, which is selected among the plurality of independent command lines, in the second operation mode and transmits the duplicated command as the common command to the common command line.

### CROSS-REFERENCE TO RELATED APPLICATIONS

The present application claims priority of Korean Patent Application No. 10-2014-0059707, filed on May 19, 2014, which is incorporated herein by reference in its entirety.

### BACKGROUND

1. Field

Exemplary embodiments relate to a semiconductor design technology, and more particularly, to an effective command transmission operation of a semiconductor device.

2. Description of the Related Art

In general, a plurality of internal circuits is included in a semiconductor device. Since the internal circuits generally perform operations independently from each other, commands have to be independently provided to the internal circuits.

For example, a plurality of memory banks is included in a semiconductor memory device. Since each of the memory banks performs active/read/write/precharge operations independently, commands have to be independently inputted to the memory banks.

Meanwhile, each of the internal circuits receives not one type of a command but diverse types of commands.

For example, row commands in relation to a row operation such as active/precharge commands and column commands in relation to column operations such as read/write commands are inputted to each of the memory banks included in the semiconductor memory device.

As described above, each of the internal circuits has to be able to receive diverse types of commands independently. Therefore, commands applied from outside to a semiconductor device have to be transmitted not only in parallel according to the number of internal circuits included in the semiconductor device but also being divided according to types of the commands.

When multiple commands are transmitted to the semiconductor device at the same time, interference may occur between command lines through which the multiple commands are transmitted due to coupling effects. When the interference between the command lines occurs, the internal circuits may perform the operations incorrectly.

### SUMMARY

Exemplary embodiments of the present invention are directed to a semiconductor device including a plurality of internal circuits or a plurality of semiconductor chips that may have a structure capable of effectively transmitting diverse types of commands.

In accordance with an embodiment of the present invention, A semiconductor device includes: a plurality of internal circuits which receive commands through a plurality of independent command lines in a first operation mode and receive a common command through a common command line in a second operation mode; and an operation control block which duplicates a command applied through a representative independent command line, which is selected among the plurality of independent command lines, in the second operation mode and transmits the duplicated command as the common command to the common command line. The semiconductor device further includes: a command generation block which generates a first operation command in the first operation mode and outputs the first operation command to one or more of the plurality of independent command lines in response to a circuit selection signal, and generates a second operation command in the second operation mode and outputs the second operation command to the representative independent command line. Wherein the operation control block couples the representative independent command line with the common command line in the second operation mode and disconnects the representative independent command line from the common command line in the first operation mode. Wherein the plurality of internal circuits are coupled with the plurality of independent command lines and are disconnected from the common command line in the first operation mode, and the plurality of internal circuits disconnected from the plurality of independent command lines are commonly coupled with the common command line in the second operation mode. Wherein the plurality of internal circuits, upon receiving the second operation command in the second operation mode, simultaneously perform a predetermined second operation. Wherein one or more of the plurality of internal circuits, to which the first operation command is transmitted in response to the circuit selection signal in the first operation mode, independently perform a predetermined first operation.

In accordance with another embodiment of the present invention, A semiconductor device includes: N memory banks which receive M commands through M*N independent command lines in a normal mode and receive a common command through a common command line in a test mode, wherein M and N are integers, N is a total number of memory banks, and M is a total number of operations performed by the N memory banks; and an operation control block which duplicates a command applied through a representative independent command line, which is selected among the M*N independent command lines, in the test mode and transmits the duplicated command as the common command to the common command line. The semiconductor device further includes: a command generation block which generates a normal command in the normal mode and outputs the normal command to one or more of the M*N independent command lines in response to a bank address, and generates a test command in the test mode and outputs the test command to the representative independent command line. Wherein the operation control block couples the representative independent command line with the common command line in the test mode, and disconnects the representative independent command line from the common command line in the normal mode. Wherein the N memory banks are coupled with the M*N independent command lines and are disconnected from the common command line in the normal mode, and wherein the N memory banks are disconnected from the M*N independent command lines and are commonly coupled with the common command line in the test mode. Wherein the N memory banks, which commonly share the test command in the test mode, simultaneously perform a predetermined test operation. Wherein one or more of the N memory banks, to which the normal command is transmitted in response to the bank address in the normal mode, independently perform a predetermined normal operation. Wherein the test mode is a compression test mode, the test command is an active command, and the N memory banks are simultaneously enabled in the predetermined test operation.

In accordance with another embodiment of the present invention, A semiconductor device includes: a command generation block suitable for being coupled to a first or a second memory circuit in a first operation mode and further suitable for being disconnected from both of the first and the second memory circuits in a second operation mode, and an operation control block suitable for being disconnected from both of the first and the second memory circuits in the first operation mode and further suitable for being commonly coupled to both of the first and the second memory circuits in the second operation mode. Wherein, in the first operation mode, the command generation block generates a first command signal in response to an input command signal, selects a memory circuit between the first and the second memory circuits in response to a circuit selection signal, and transmits the first command signal to the selected memory circuit. Wherein, upon receiving the first command signal, the selected memory circuit performs a first operation, and wherein the first operation includes an active operation, a precharge operation, a read operation, a write operation, or a combination thereof. Wherein, iii the second operation mode, the operation control block receives a second command signal and transmits the second command signal to both of the first and the second memory circuits. Wherein, upon receiving the second command signal, both of the first and second memory circuits perform the second operation, and wherein the second operation includes an active operation, a precharge operation, a read operation, a write operation, or a combination thereof. Wherein the second operation mode is a test mode. The semiconductor device further includes third and fourth memory circuits, wherein the command generation block is suitable for being coupled to the first, the second, the third, or the fourth memory circuit in the first operation mode and further suitable for being disconnected from all of the first through the fourth memory circuits in the second operation mode, and wherein the operation control block is suitable for being disconnected from all of the first through the fourth memory circuits in the first operation mode and further suitable for being commonly coupled to two or more of the first through the fourth memory circuits in the second operation mode.

### BRIEF DESCRIPTION OF THE DRAWINGS

FIG. 1 is a block diagram illustrating a command transmission path of a general semiconductor memory device.

FIG. 2 is a timing diagram illustrating a command transmission operation in a command transmission path of the general semiconductor memory device shown in FIG. 1.

FIG. 3 is a block diagram illustrating a command transmission path of a semiconductor memory device in accordance with a first embodiment.

FIG. 4 is a timing diagram illustrating a command transmission operation in the command transmission path of the semiconductor memory device shown in FIG. 3.

FIG. 5 is a block diagram illustrating a command transmission path of a semiconductor memory device in accordance with a second embodiment.

FIG. 6 is a timing diagram illustrating a command transmission operation in the command transmission path of the semiconductor memory device shown in FIG. 5.

### DETAILED DESCRIPTION

Exemplary embodiments are described below in more detail with reference to the accompanying drawings. The embodiments presented are merely examples and are not intended to be limitative.

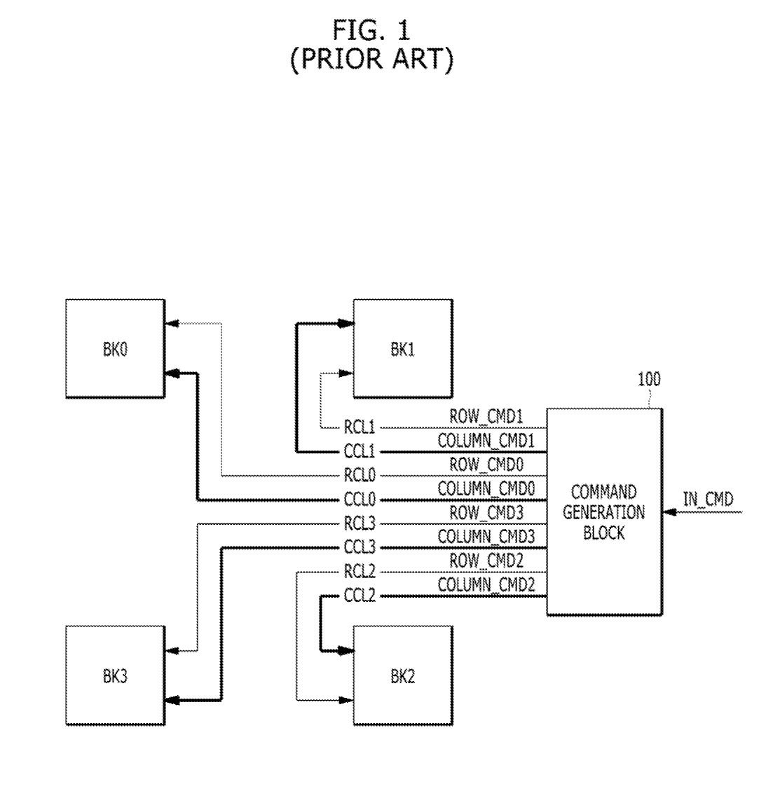

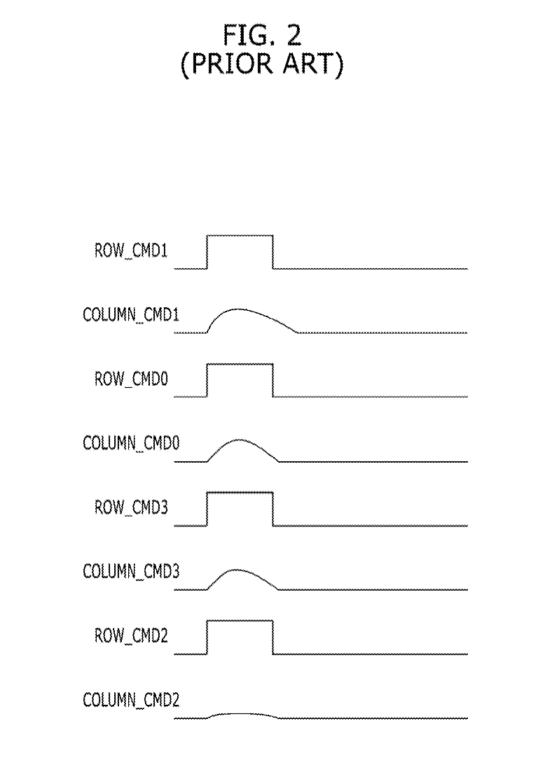

FIG. 1 is a block diagram illustrating a command transmission path of a general semiconductor memory device. FIG. 2 is a timing diagram illustrating a command transmission operation in the command transmission path of the general semiconductor memory device shown in FIG. 1.

Referring to FIG. 1, the general semiconductor memory device includes a plurality of memory banks BK0, BK1, BK2 and BK3, a command generation block 100, and a plurality of independent command lines RCL0, RCL1, RCL2, RCL3, CCL0, CCL1, CCL2 and CCL3.

The memory bank BK0 is coupled to the independent command lines RCL0 and CCL0, and the memory bank BK1 is coupled to the independent, command lines RCL1 and CCL1. The memory bank BK2 is coupled to the independent command lines RCL2 and CCL2, and the memory bank BK3 is coupled to the independent command lines RCL3 and CCL3.

For example, the independent command lines RCL0, RCL1, RCL2, RCL3, CCL0, CCL1, CCL2 and CCL3 may include a plurality of independent row command lines RCL0, RCL1, RCL2 and RCL3 for receiving commands ROW_CMD0, ROW_CMD1, ROW_CMD2 and ROW_CMD3 related to a row operation and a plurality of independent column command lines CCL0, CCL1, CCL2 and CCL3 for receiving commands COLUMN_CMD0, COLUMN_CMD1, COLUMN_CMD2 and COLUMN_CMD3 related to a column operation. The total number of the independent row command lines RCL0, RCL1, RCL2 and RCL3 is 4, which is same as the number of the memory banks BK0, BK1, BK2 and BK3. Similarly, the total number of the independent column command lines CCL0, CCL1, CCL2 and CCL3 is 4, which is same as the number of the memory banks BK0, BK1, BK2 and BK3.

In other words, the 0^{th} memory bank BK0 corresponds to the 0^{th} independent row command line RCL0 and the 0^{th} independent column command line CCL0. The first memory bank BK1 corresponds to the first independent row command line RCL1 and the first independent column command line CCL1. The second memory bank BK2 corresponds to the second independent row command line RCL2 and the second independent column command line CCL2. The third memory bank BK3 corresponds to the third independent row command line RCL3 and the third independent column command line CCL3.

The number of the independent command lines RCL0, RCL1, RCL2, RCL3, CCL0, CCL1, CCL2 and CCL3 for respectively transmitting one command set, such as the commands ROW_CMD0, ROW_CMD1, ROW_CMD2 and ROW_CMD3 related to the row operation and the commands COLUMN_CMD0, COLUMN_CMD1, COLUMN_CMD2 and COLUMN_CMD3 related to the column operation, varies depending on the number of the memory banks BK0, BK1, BK2 and BK3.

The command generation block 100 may generate the row commands ROW_CMD0, ROW_CMD1, ROW_CMD2 and ROW_CMD3 related to the row operation and the column commands COLUMN_CMD0, COLUMN_CMD1, COLUMN_CMD2 and COLUMN_CMD3 related to the column operation in response to an input command IN_CMD.

The row commands ROW_CMD0, ROW_CMD1, ROW_CMD2 and ROW_CMD3 are transmitted to the memory banks BK0, BK1, BK2 and BK3 through the independent row command lines RCL0, RCL1, RCL2 and RCL3. In other words, the 0^{th} row command ROW_CMD0 is transmitted to the 0^{th} memory bank BK0 through the 0^{th} independent row command line RCL0. The first row command ROW_CMD1 is transmitted to the first memory bank BK1 through the first independent row command line RCL1. The second row command ROW_CMD2 is transmitted to the second memory bank BK2 through the second independent row command line RCL2. The third row command ROW_CMD3 is transmitted to the third memory bank BK3 through the third independent row command line RCL3.

The column commands COLUMN_CMD0, COLUMN_CMD1, COLUMN_CMD2 and COLUMN_CMD3 are transmitted to the memory banks BK0, BK1, BK2 and BK3 through the independent column command lines CCL0, CCL1, CCL2 and CCL3. In other words, the 0^{th} column command COLUMN_CMD0 is transmitted to the 0^{th} memory bank BK0 through the 0^{th} independent column command line CCL0. The first column command COLUMN_CMD1 is transmitted to the first memory bank BK1 through the first independent column command line CCL1. The second column command COLUMN_CMD2 is transmitted to the second memory bank BK2 through the second independent column command line CCL2. The third column command COLUMN_CMD3 is transmitted to the third memory bank BK3 through the third independent column command line CCL3.

Meanwhile, the memory banks BK0, BK1, BK2 and BK3 do not simultaneously operate in a data input/output operation of the general semiconductor memory device. For example, a section where the 0^{th} memory bank BK0 among the memory banks BK0, BK1, BK2 and BK3 operates in response to the command related to the row operation may be a section where the first memory bank BK1 operates in response to the command related to the column operation.

Therefore, in the data input/output operation of the general semiconductor memory device, even though the row commands ROW_CMD0, ROW_CMD1, ROW_CMD2 and ROW_CMD3 are simultaneously transmitted to the memory banks BK0, BK1, BK2 and BK3 as shown in FIG. 2, waveforms of the column commands COLUMN_CMD0, COLUMN_CMD1, COLUMN_CMD2 and COLUMN_CMD3 may not change due to a coupling effect between the row commands ROW_CMD0, ROW_CMD1, ROW_CMD2 and ROW_CMD3.

However, in an operation of simultaneously operating the memory banks BK0 BK1, BK2 and BK3 like a compression test mode of a semiconductor memory device, the row commands ROW_CMD0, ROW_CMD1, ROW_CMD2 and ROW_CMD3 are simultaneously transmitted to the memory banks BK0, BK1, BK2 and BK3 as shown in FIG. 2, and the waveforms of the column commands COLUMN_CMD0, COLUMN_CMD1, COLUMN_CMD2 and COLUMN_CMD3 may change because the coupling effect between the row commands ROW_CMD0, ROW_CMD1, ROW_CMD2 and ROW_CMD3 causes interference. When the waveforms of the column commands COLUMN_CMD0, COLUMN_CMD1, COLUMN_CMD2 and COLUMN_CMD3 change, an unintentional column operation may be performed on the memory banks BK0, BK1, BK2 and BK3 even when the column operation is not intended.

### First Embodiment

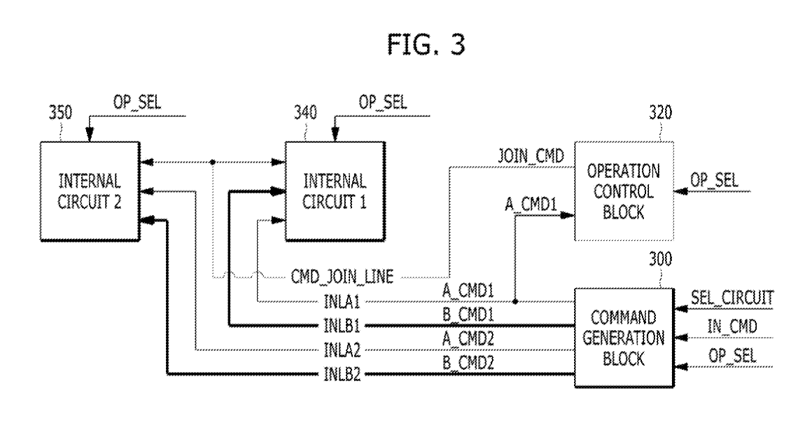

FIG. 3 is a block diagram illustrating a command transmission path of a semiconductor memory device in accordance with a first embodiment.

Referring to FIG. 3, the semiconductor memory device includes a plurality of internal circuits 340 and 350, a command generation block 300, an operation control block 320, a plurality of independent command lines INLA1, INLA2, INLB1 and INLB2, and one common command line CMD_JOIN_LINE.

The internal circuit 340 corresponds to the independent command lines INLA1 and INLB1, and the internal circuit 350 corresponds to the independent command lines INLA2 and INLB2.

For example, the independent command lines INLA1, INLA2, INLB1 and INLB2 respectively may include a plurality of independent A command lines INLA1 and INLA2 for receiving commands A_CMD1 and A_CMD2 related to a predetermined A operation and a plurality of independent B command lines INLB1 and INLB2 for receiving commands B_CMD1 and B_CMD2 related to a predetermined B operation. The total number of the independent A command lines INLA1 and INLA2 is 2, which is same as the number of the internal circuits 340 and 350. Similarly, the total number of the independent B command lines INLB1 and INLB2 is 2, which is same as the number of the internal circuits 340 and 350.

In other words, the first internal circuit 340 corresponds to the first independent A command line INLA1 and the first independent B command line INLB1. The second internal circuit 350 corresponds to the second independent A command line INLA2 and the second independent B command line INLB2.

The number of the independent command lines INLA1, INLA2, INLB1 and INLB2 for transmitting the commands A_CMD1 and A_CMD2 which are related to the A operation and the commands B_CMD1 and B_CMD2 which are related to the B operation respectively correspond to the number of the internal circuits 340 and 350.

The internal circuits 340 and 350 are coupled to the common command line CMD_JOIN_LINE in common. In other words, the common command line CMD_JOIN_LINE are commonly coupled to the first internal circuit 340 as well as the second internal circuit 350.

The relationship between the internal circuits 340 and 350, the independent command lines INLA1, INLA2, INLB1 and INLB2, and the common command line CMD_JOIN_LINE changes based on whether the internal circuits 340 and 350 operate in a first operation mode or in a second operation mode.

The internal circuits 340 and 350 receive the commands A_CMD1, A_CMD2, B_CMD1 and B_CMD2 through the independent command lines INLA1, INLA2, INLB1 and INLB2 respectively in the first operation mode and a command JOIN_CMD in common through the common command line CMD_JOIN_LINE in the second operation mode.

The command generation block 300 generates a first operation command A_CMD1, A_CMD2, B_CMD1 or B_CMD2 in the first operation mode and a second operation command A_CMD1 in the second operation mode in response to an input command IN_CMD. The second operation command A_CMD1 is also included in the first operation command A_CMD1, A_CMD2, B_CMD1 or B_CMD2. This means that one command among diverse types of commands which may be generated as the first operation command A_CMD1, A_CMD2, B_CMD1 or B_CMD2 in the first operation mode may be selected as the second operation command A_CMD1. For example, the drawing shows that the first operation command A_CMD1 transmitted to the first internal circuit 340 in relation to the A operation in the first operation mode is generated as the second operation command A_CMD1. Different from what is shown in the drawing, in another embodiment, the first operation command B_CMD2 transmitted to the second internal circuit 350 in relation to the B operation in the first operation mode may be generated as the second operation command A_CMD1.

The first operation command A_CMD1, A_CMD2, B_CMD1 or B_CMD2 which is generated in the command generation block 300 in the first operation mode is outputted to one or more independent command lines INLA1, INLA2, INLB1 or INLB2 which is selected from, in response to a circuit selection signal SEL_CIRCUIT, among the independent command lines INLA1, INLA2, INLB1 and INLB2.

The second operation command A_CMD1 generated in the command generation block 300 in the second operation mode is outputted to one representative independent command line INLA1 which is selected among the independent command lines INLA1, INLA2, INLB1 and INLB2. The representative independent command line INLA1 indicates an independent command line where the second operation command A_CMD1 is outputted. For example, when the first operation command A_CMD1, which is transmitted to the first internal circuit 340 in relation to the A operation in the first operation mode, is designated as the second operation command A_CMD1 as shown in the drawing, the corresponding independent command line INLA1 is the representative independent command line INLA1. Different from what is shown in the drawing, in another embodiment, when the first operation command B_CMD2 which is transmitted to the second internal circuit 350 in relation to the B operation in the first operation mode may be designated as the second operation command, the corresponding independent command line INLB2 may be the representative independent command line.

To be specific, the first operation command A_CMD1, A_CMD2, B_CMD1 or B_CMD2, which is generated in the command generation block 300 in the first operation mode, may include the commands A_CMD1 and A_CMD2 related to the A operation and the commands B_CMD1 and B_CMD2 related to the B operation according to type of input command IN_CMD. Also, the first operation command A_CMD1, A_CMD2, B_CMD1 or B_ CMD2 may include the commands A_CMD1 and B_CMD1 related to the operation of the first internal circuit 340 and the commands A_CMD2 and B_CMD2 related to the operation of the second internal circuit 350 according to the circuit selection signal SEL_CIRCUIT. The input command IN_CMD and the circuit selection signal SEL_CIRCUIT are signals for determining which internal circuit among the internal circuits 340 and 350 performs which operation in the first operation mode, and they may be either generated inside of the semiconductor device or inputted from the outside of the semiconductor device.

The first independent A command A_CMD1 among the first operation command A_CMD1, A_CMD2, B_CMD1 and B_CMD2 is transmitted to the first internal circuit 340 through the first independent A command line INLA1 in the first operation mode. The second independent A command A_CMD2 is transmitted to the second internal circuit 350 through the second independent A command line INLA2 in the first operation mode. The first independent B command B_CMD1 is transmitted to the first internal circuit 340 through the first independent B command line INLB1 in the first operation mode. The second independent B command B_CMD2 is transmitted to the second internal circuit 350 through the second independent B command line INLB2 in the first operation mode.

As described above, the first operation commands A_CMD1, A_CMD2, B_CMD1 and B_CMD2 are transmitted to the internal circuits 340 and 350 in the first operation mode through the corresponding independent command lines INLA1, INLA2, INLB1 and INLB2, respectively.

The second operation command A_CMD1 generated in the command generation block 300 in the second operation mode is loaded on the common command line CMD_JOIN_LINE as the common command JOIN_CMD by the operation control block 320 and transmitted to both of the internal circuits 340 and 350. In other words, the second operation command A_CMD1 is loaded on the common command line CMD_JOIN_LINE serving as the common command JOIN_CMD and transmitted to both of the first internal circuit 340 and the second internal circuit 350. The second operation command A_CMD1 may be the first operation command A_CMD1 transmitted to the first internal circuit 340 in relation to the A operation in the first operation mode as described in the drawing, and it may be the first operation commands A_CMD2, B_CMD1 or B_CMD2 in another embodiment. That is, regardless of what is designated as the second operation command, the second operation command is loaded on the common command line CMD_JOIN_LINE as the common command JOIN_CMD by the operation control block 320 in the second operation mode and transmitted to the internal circuits 340 and 350 in common.

The operation control block 320 duplicates the second operation command A_CMD1 applied through the representative independent command line INLA1 and transmits the duplicated command to the common command line CMD_JOIN_LINE in the second operation mode. For this process, the operation control block 320 couples the representative independent command line INLA1 to the common command line CMD_JOIN_LINE in the second operation mode. On the contrary, the operation control block 320 does not couple the representative independent command line INLA1 to the common command line CMD_JOIN_LINE in the first operation mode.

As described above, in the first operation mode, one or more internal circuits 340 and 350, in response to the circuit selection signal SEL_CIRCUIT, receive the first operation command A_CMD1, A_CMD2, B_CMD1 or B_CMD2 through the corresponding independent command line INLA1, INLA2, INLB1 or INLB2 and perform the predetermined first operation.

In the second operation mode, the internal circuits 340 and 350 simultaneously receive the second operation command A_CMD1, i.e., the common command JOIN_CMD, through the command line CMD_JOIN_LINE and perform the predetermined second operation.

The internal circuits 340 and 350 are individually coupled to the independent command lines INLA1, INLA2, INLB1 and INLB2 in the first operation mode and are not coupled to the common command line CMD_JOIN_LINE. Therefore, although the voltage level of the common command line CMD_JOIN_LINE unpredictably changes in the first operation mode the change has no influence on the operations of the internal circuits 340 and 350.

Likewise, the internal circuits 340 and 350 are not individually coupled with the independent command lines INLA1, INLA2, INLB1 and INLB2 but are commonly coupled to the common command line CMD_JOIN_LINE in the second operation mode. Thus, although voltage levels of the independent command lines INLA1, INLA2, INLB1 and INLB2 change, the changes have no influence on the operations of the internal circuits 340 and 350 in the second operation mode.

In the aforementioned structure, the first operation mode and the second operation mode may be determined by an operation selection signal OP_SEL. For example, the operation selection signal OP_SEL may be enabled in the first operation mode, and the operation selection signal OP_SEL may be disabled in the second operation mode.

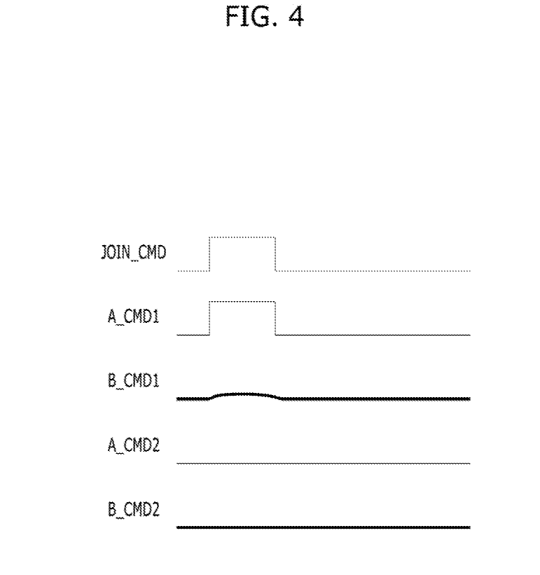

FIG. 4 is a timing diagram illustrating a command transmission operation in the command transmission paths of the semiconductor memory device shown in FIG. 3.

Before referring to FIG. 4, the independent command lines INLA1, INLA2, INLB1 and INLB2 are disposed adjacent to each other as shown in FIG. 3. Therefore, if the independent command lines INLA1 and INLA2 related to the A operation among the independent command lines INLA1, INLA2, INLB1 and INLB2 simultaneously toggle, voltage levels of the independent command lines INLB1 and INLB2 related to the B operation would change due to interference caused by a coupling effect. In other words, if the internal circuits 340 and 350 use the independent command lines INLA1 and INLA2 related to the A operation to perform the A operation, an error in which the B operation is performed due to the interference caused by the coupling effect would occur.

Similarly, if the independent command lines INLB1 and INLB2 related to the B operation among the independent command lines INLA1, INLA2, INLB1 and INLB2 simultaneously toggle, voltage levels of the independent command lines INLA1 and INLA2 related to the A operation would change due to interference caused by a coupling effect. In other words, if the internal circuits 340 and 350 use the independent command lines INLB1 and INLB2 related to the B operation to perform the B operation, an error in which the A operation is performed due to the interference caused by the coupling effect would occur.

Referring to FIG. 4, the occurrence of the interference caused by the coupling effect may be minimized since the semiconductor device in accordance with the first embodiment transmits the commands A_CMD1 serving as the common command JOIN_CMD to both of the internal circuits 340 and 350 through the common command line CMD_JOIN_LINE, instead of individually transmitting the command A_CMD1, A_CMD2, B_CMD1 or B_CMD2 to the internal circuits 340 and 350 through the independent command lines INLA1, INLA2, INLB1 or INLB2 in a predetermined operation mode, i.e., the second operation mode, where the internal circuits 340 and 350 have to simultaneously perform the A or B operation.

The semiconductor device individually transmits the command A_CMD1, A_CMD2, B_CMD1 or B_CMD2 to the internal circuits 340 and 350 through the independent command lines INLA1, INLA2, INLB1 and INLB2 in a normal operation mode, i.e., the first operation mode, where the interference caused by the coupling effect is not likely to occur since the internal circuits 340 and 350 do not perform the A operation or the B operation at the same time.

In accordance with the first embodiment, as described above, the common command line CMD_JOIN_LINE capable of transmitting the predetermined commands A_CMD1→JOIN_CMD in common to the internal circuits 340 and 350 in the second operation mode is additionally provided so that the predetermined commands A_CMD1 may be simultaneously transmitted as the common command JOIN_CMD to both of the internal circuits 340 and 350 in the second operation mode where the internal circuits 340 and 350 included in the semiconductor device simultaneously perform a predetermined operation.

Therefore, interference may be prevented from occurring due to the coupling effect between the independent command lines INLA1, INLA2, INLB1 and INLB2 in the second operation mode since the predetermined commands A_CMD1 are simultaneously transmitted using the common command JOIN_CMD to both of the internal circuits 340 and 350 through the common command line CMD_JOIN_LINE, instead of transmitting the predetermined commands A_CMD1 as the common command JOIN_CMD to the internal circuits 340 and 350 through the independent command lines INLA1, INLA2, INLB1 and INLB2 for selectively transmitting the command A_CMD1, A_CMD2, B_CMD1 or B_CMD2 to the internal circuits 340 and 350 in the second operation mode.

Also, current consumption may greatly decrease as compared with the case when the predetermined commands A_CMD1 are simultaneously transmitted as the common command JOIN_CMD to the internal circuits 340 and 350 through the independent command lines INLA1, INLA2, INLB1 and INLB2.

### Second Embodiment

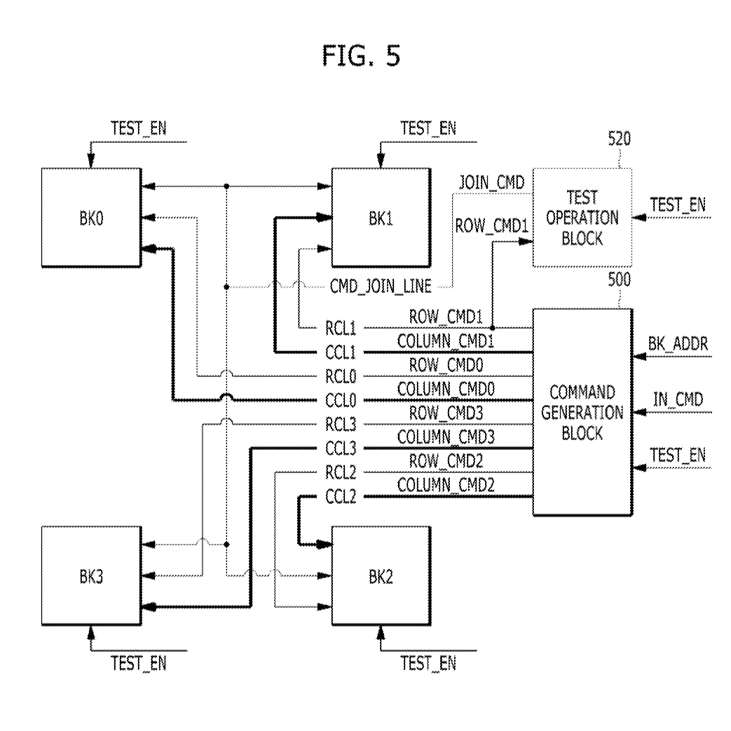

FIG. 5 is a block diagram illustrating a command transmission path of a semiconductor memory device in accordance with a second embodiment.

Referring to FIG. 5, the semiconductor memory device includes N memory banks BK0, BK1, BK2 and BK3, a command generation block 500, a test operation block 520, M*N independent command lines RCL0, RCL1, RCL2, RCL3, CCL0, CCL1, CCL2 and CCL3, and one common command line CMD_JOIN_LINE. M is an integer and denotes the total number of operations performed by the memory circuits. N is an integer and denotes the total number of banks. For example, in an embodiment shown in FIG. 1, the memory circuits perform two kinds of operations such as row operation and column operation, M value is 2. In addition, in FIG. 1, the total number of banks is 4 and thus the value of N is 4.

In the embodiment shown in FIG. 5, N memory banks BK0, BK1, BK2 and BK3 are provided and M*N independent command lines RCL0, RCL1, RCL2, RCL3, CCL0, CCL1, CCL2 and CCL3 are provided.

For example, the M*N independent command lines RCL0, RCL1, RCL2, RCL3, CCL0, CCL1, CCL2 and CCL3 may include N independent row command lines RCL0, RCL1, RCL2 and RCL3 for receiving commands ROW_CMD0, ROW_CMD1, ROW_CMD2 and ROW_CMD3 related to row operation and N independent column command lines CCL0, CCL1, CCL2 and CCL3 for receiving commands COLUMN_CMD0, COLUMN_CMD1, COLUMN_CMD2 and COLUMN_CMD3 related to column operation. The total number of the N independent row command lines RCL0, RCL1, RCL2 and RCL3 is 4, which is same as the number of the N memory banks BK0, BK1, BK2 and BK3. Similarly, the total number of the N independent column command lines CCL0, CCL1, CCL2 and CCL3 is 4, which is same as the number of the N memory banks BK0 BK1, BK2 and BK3.

In other words, the 0^{th} memory bank BK0 is coupled to the 0^{th} independent row command line RCL0 and the 0^{th} independent column command fine CCL0. The first memory bank BK1 is coupled to the first independent row command line RCL1 and the first independent column command line CCL1. The second memory bank BK2 is coupled to the second independent row command line RCL2 and the second independent column command line CCL2. The third memory bank BK3 is coupled to the third independent row command line RCL3 and the third independent column command line CCL3.

The M*N independent command lines RCL0, RCL1, RCL2, RCL3, CCL0, CCL1, CCL2 and CCL3 may be divided into a first command set including the commands ROW_CMD0, ROW_CMD1, ROW_CMD2 and ROW_CMD3 related to the row operation and a second command set including commands COLUMN_CMD0, COLUMN_CMD1, COLUMN_CMD2 and COLUMN_CMD3 related to the column operation according to the types of operations. The number of commands included in each of the first and the second sets is 4 which is same as the number of the N memory banks BK0, BK1, BK2 and BK3.

As described in the aforementioned structure, N may be 4. Similarly, M may be 2. The aforementioned structure is just one embodiment. Thus, the N and M values may be different in another embodiment.

The N memory banks BK0, BK1, BK2 and BK3 are commonly coupled to the common command line CMD_JOIN_LINE. In other words, the common command line CMD_JOIN_LINE is coupled to the 0^{th} memory bank BK0, the first memory bank BK1, the second memory bank BK2 and the third memory bank BK3.

The relationship between the N memory banks BK0, BK1, BK2 and BK3, the M*N independent command lines RCL0, RCL1, BCL2, RCL3, CCL0, CCL1, CCL2 and CCL3, and the common command line CMD_JOIN_LINE changes depending on whether the N memory banks BK0, BK1, BK2 and BK3 operate in a normal mode or in a test mode.

The N memory banks BK0, BK1, BK2 and BK3 receive the commands ROW_CMD0, ROW_CMD1, ROW_CMD2, ROW_CMD3, COLUMN_CMD0, COLUMN_CMD1, COLUMN_CMD2 and COLUMN_CMD3 through the M*N independent command lines RCL0, RCL1, RCL2, RCL3, CCL0, CCL1, CCL2 and CCL3 respectively in the normal mode and commonly receive a command JOIN_CMD through the common command line CMD_JOIN_LINE in the test mode.

The command generation block 500 generates a normal command ROW_CMD0, ROW_CMD1, ROW_CMD2, ROW_CMD3, COLUMN_CMD0, COLUMN_CMD1, COLUMN_CMD2 or COLUMN_CMD3 in the normal mode and a test command ROW_CMD1 in the test mode in response to an input command IN_CMD. Herein, the test command ROW_CMD1 is also included in the normal command ROW_CMD0, ROW_CMD1, ROW_CMD2, ROW_CMD3, COLUMN_CMD0, COLUMN_CMD1, COLUMN_CMD2 or COLUMN_CMD3. This means that one command among diverse types of commands which may be generated as the normal command ROW_CMD0, ROW_CMD1, ROW_CMD2, ROW_CMD3, COLUMN_CMD0, COLUMN_CMD1, COLUMN_CMD2 or COLUMN_CMD3 in the normal mode may be selected as the test command ROW_CMD1. For example, the drawing shows that the normal command ROW_CMD1 which is transmitted to the first memory bank BK1 in relation to the row operation in the normal mode is designated as the test command ROW_CMD1. In another embodiment, the normal command COLUMN_CMD3 transmitted to the third memory bank BK3 in relation to the column operation in the normal mode may be generated as the test command.

The normal command ROW_CMD0, ROW_CMD1 ROW_CMD2, ROW_CMD3, COLUMN_CMD0, COLUMN_CMD1, COLUMN_CMD2 or COLUMN_CMD3 which is generated in the command generation block 500 in the normal mode is outputted to one or more independent command lines RCL0, RCL1, RCL2, RCL3, CCL0, CCL1, CCL2 or CCL3 among the M*N independent command lines RCL0, RCL1, RCL2, RCL3, CCL0, CCL1, CCL2 and CCL3, in response to a bank address BK_ADDR.

The test command ROW_CMD1 which is generated in the command generation block 500 in the test mode is outputted to a representative independent command line RCL1. The representative independent command line RCL1 is an independent command line from the M*N independent command lines RCL0, RCL1, RCL2, RCL3, CCL0, CCL1, CCL2 and CCL3. The test command ROW_CMD1 is outputted to the representative independent command line RCL1. For example, when the normal command ROW_CMD1 which is transmitted to the first memory bank BK1 in relation to the row operation in the normal mode is designated as the test command ROW_CMD1 as shown in the drawing, the corresponding independent command line RCL1 is set as the representative independent command line RCL1. In another embodiment, when the normal command COLUMN_CMD3 which is transmitted to the third memory bank BK3 in relation to the column operation in the normal mode is designated as the test command, the corresponding independent command line CCL3 may be set as the representative independent command line.

To be specific, the normal command ROW_CMD0, ROW_CMD1, ROW_CMD2, ROW_CMD3, COLUMN_CMD0, COLUMN_CMD1, COLUMN_CMD2 or COLUMN_CMD3 which is generated in the command generation block 500 in the normal mode may include the row commands ROW_CMD0, ROW_CMD1, ROW_CMD2 and ROW_CMD3 related to the row operation and the column commands COLUMN_CMD0, COLUMN_CMD1, COLUMN_CMD2 and COLUMN_CMD3 related to the column operation according to type of the input command IN_CMD. Also, the normal command ROW_CMD0, ROW_CMD1, ROW_CMD2, ROW_CMD3, COLUMN_CMD0, COLUMN_CMD1, COLUMN_CMD2 or COLUMN_CMD3 may include the commands ROW_CMD0 and COLUMN_CMD0 related to the operation of the 0^{th} memory bank BK0, the commands ROW_CMD1 and COLUMN_CMD1 related to the operation of the first memory bank BK1, the commands ROW_CMD2 and COLUMN_CMD2 related to the operation of the second memory bank BK2, and the commands ROW_CMD3 and COLUMN_CMD3 related to the operation of the third memory bank BK3 according to the bank address BK_ADDR. The input command IN_CMD and the bank address BK_ADDR are signals for determining which memory bank among the N memory banks BK0, BK1, BK2 and BK3 performs which operation in the normal mode, and they are inputted outside the semiconductor memory device.

The 0^{th} row command ROW_CMD0 among the normal command ROW_CMD0, ROW_CMD1, ROW_CMD2, ROW_CMD3, COLUMN_CMD0, COLUMN_CMD1, COLUMN_CMD2 or COLUMN_CMD3 is transmitted to the 0^{th} memory bank BK0 through the 0^{th} independent row command line RCL0 in the normal mode. The first row command ROW_CMD1 is transmitted to the first memory bank BK1 through the first independent row command line RCL1 in the normal mode. The second row command ROW_CMD2 is transmitted to the second memory bank BK2 through the second independent row command line RCL2 in the normal mode. The third row command ROW_CMD3 is transmitted to the third memory bank BK3 through the third independent row command line RCL3 in the normal mode. The 0^{th} column command COLUMN_CMD0 is transmitted to the 0^{th} memory bank BK0 through the 0^{th} independent column command line RCL0 in the normal mode. The first column command COLUMN_CMD1 is transmitted to the first memory bank BK1 through the first independent column command line RCL1 in the normal mode. The second column command COLUMN_CMD2 is transmitted to the second memory bank BK2 through the second independent column command line RCL2 in the normal mode. The third column command COLUMN_CMD3 is transmitted to the third memory bank BK3 through the third independent column command line RCL3 in the normal mode.

As described above, the normal command ROW_CMD0, ROW_CMD1, ROW_CMD2, ROW_CMD3, COLUMN_CMD0, COLUMN_CMD1, COLUMN_CMD2 or COLUMN_CMD3 which is transmitted to the N memory banks BK0, BK1, BK2 or BK3 in the normal mode is transmitted to the N memory bank BK0, BK1, BK2 or BK3 through the corresponding independent command line RCL0, RCL1, RCL2, RCL3, CCL0, CCL1, CCL2 or CCL3.

The test command ROW_CMD1 which is generated in the command generation block 500 in the test mode is loaded on the common command line CMD_JOIN_LINE as the common command JOIN_CMD by the test operation block 520 and transmitted to all of the N memory banks BK0, BK1, BK2 and BK3. In other words, the test command ROW_CMD1 is loaded on the common command line CMD_JOIN_LINE as the common command JOIN_CMD and transmitted to the 0^{th} memory bank BK0, the first memory bank BK1, the second memory bank BK2 and the third memory bank BK3. The test command ROW_CMD1 may be the normal command ROW_CMD1 which is transmitted to the first memory bank BK1 in relation to the row operation in the normal mode as described in the drawing. In another embodiment, the common command JOIN_CMD may be another normal command ROW_CMD0, ROW_CMD1, ROW_CMD2, ROW_CMD3, COLUMN_CMD0, COLUMN_CMD1, COLUMN_CMD2 or COLUMN_CMD3. Regardless of what the test command ROW. CMD1 is, the common command JOIN_CMD is loaded on the common command line CMD_JOIN_LINE by the test operation block 520 in the test mode and transmitted to all of the N memory banks BK0, BK1, BK2 and BK3.

The test operation block 520 duplicates the test command ROW_CMD1 applied through the representative independent command line RCL1 and transmits the duplicated command to the common command line CMD_JOIN_LINE as the common command JOIN_CMD in the test mode. For this process, the test operation block 520 couples the representative independent command line RCL1 to the common command line CMD_JOIN_LINE in the test mode. In contrast, the test operation block 520 does not couple the representative independent command line RCL1 to the common command line CMD_JOIN_LINE in the normal mode.

As described above, in the normal mode, one or more memory banks BK0, BK1, BK2 or BK3 among the N memory banks BK0, BK1, BK2 and BK3 receives the normal command ROW_CMD0, ROW_CMD1, ROW_CMD2, ROW_CMD3, COLUMN_CMD0, COLUMN_CMD1, COLUMN_CMD2 or COLUMN_CMD3 in response to the bank address BK_ADDR through the corresponding independent command lines RCL0, RCL1, RCL2, RCL3, CCL0, CCL1, CCL2 and CCL3 and performs the predetermined normal operation.

In the test mode, the N memory banks BK0, BK1, BK2 and BK3 simultaneously receive the test command ROW_CMD1, i.e., the common command JOIN_CMD, through the command line CMD_JOIN_LINE and perform the predetermined test operation.

The N memory banks BK0, BK1, BK2 and BK3 are individually coupled to the M*N independent command lines RCL0, RCL1, RCL2, RCL3, CCL0, CCL1, CCL2 and CCL3 in the normal mode and are not coupled to the common command line CMD_JOIN_LINE. Therefore, although the voltage level of the common command line CMD_JOIN_LINE unpredictably changes in the normal mode, the change has no influence on the operations of the N memory banks BK0, BK1, BK2 and BK3.

The N memory banks BK0, BK1 BK2 and BK3 are not individually coupled to the M*N independent command lines RCL0, RCL1, RCL2, RCL3, CCL0, CCL1, CCL2 and CCL3 and are commonly coupled with the common command line CMD_JOIN_LINE in the test mode. Thus, although voltage levels of the M*N independent command lines RCL0, RCL1, RCL2, RCL3, CCL0, CCL1, CCL2 and CCL3 coupled to the N memory banks BK0, BK1, BK2 and BK3 change in the test mode, the change in the voltage levels of the M*N independent command lines RCL0, RCL1, RCL2, RCL3, CCL0, CCL1, CCL2 and CCL3 has no influence on operations of the N memory banks BK0, BK1, BK2 and BK3.

In the aforementioned structure, the normal mode and the test mode may be determined in response to a test enable signal TEST_EN. For example, the normal mode turns on when the test enable signal TEST_EN is disabled. In contrast, the test mode turns on when the test enable signal TEST_EN is enabled.

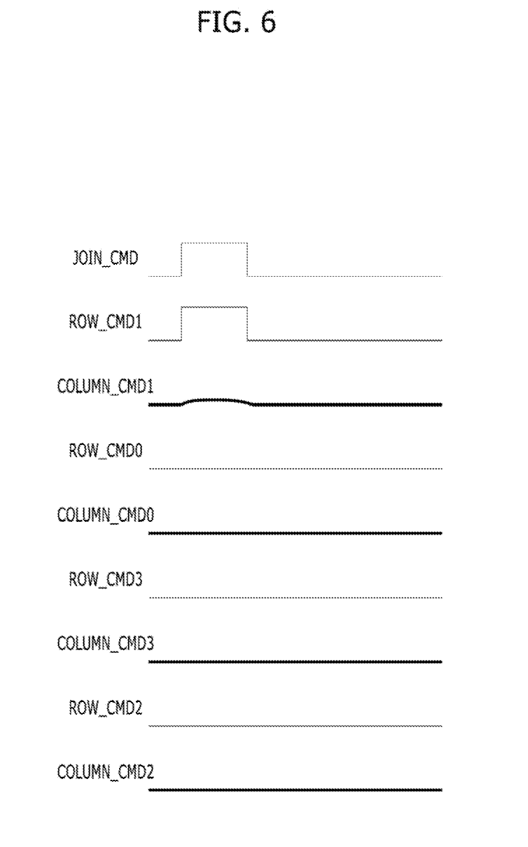

FIG. 6 is a timing diagram illustrating a command transmission operation in the command transmission path of the semiconductor memory device shown in FIG. 5.

The M*N independent command lines RCL0, RCL1, RCL2, RCL3, CCL0, CCL1, CCL2 and CCL3 are disposed adjacent to each other as shown in FIG. 5. Therefore, if the independent command lines RCL0, RCL1, RCL2 and RCL3 related to the row operation among the M*N independent command lines RCL0, RCL1, RCL2, RCL3, CCL0, CCL1, CCL2 and CCL3 simultaneously toggle in the test mode, voltage levels of the independent command lines CCL0, CCL1, CCL2 and CCL3 related to the column operation would change due to interference caused by a coupling effect as shown in FIG. 2. In other words, if the N memory banks BK0, BK1, BK2 and BK3 use the independent command lines RCL0, RCL1, RCL2 and RCL3 related to the row operation to simultaneously perform the row operation in the test mode, an error in which the column operation is performed due to the interference caused by the coupling effect may occur.

Similarly, if the independent command lines CCL0, CCL1, CCL2 and CCL3 related to the column operation among the M*N independent command lines RCL0, RCL1, RCL2, RCL3, CCL0, CCL1, CCL2 and CCL3 simultaneously toggle in the test mode, voltage levels of the independent command lines RCL0, RCL1, RCL2 and RCL3 related to the row operation would change due to interference caused by coupling effects. In other words, if the N memory banks BK0, BK1, BK2 and BK3 use the independent command lines CCL0, CCL1, CCL2 and CCL3 related to the column operation to simultaneously perform the column operation, an error in which the row operation is performed due to interference caused by the coupling effect would occur.

Referring to FIG. 6, occurrence of interference caused by the coupling effect may be minimized since the semiconductor device in accordance with the second embodiment transmits the commands ROW_CMD1 as the common command JOIN_CMD to all of the N memory banks BK0, BK1, BK2 and BK3 through the common command line CMD_JOIN_LINE, instead of individually transmitting the command ROW_CMD0, ROW_CMD1, ROW_CMD2, ROW_CMD3, COLUMN_CMD0, COLUMN_CMD1, COLUMN_CMD2 or COLUMN_CMD3 to the N memory banks BK0, BK1 BK2 and BK3 through the M*N independent command line RCL0, RCL1, RCL2, RCL3, CCL0, CCL1, CCL2 and CCL3 in the test mode where the N memory banks BK0, BK1, BK2 and BK3 simultaneously perform the row or column operation.

The semiconductor device individually transmits the command ROW_CMD0, ROW_CMD1, ROW_CMD2, ROW_CMD3, COLUMN_CMD0, COLUMN_CMD1, COLUMN_CMD2 or COLUMN_CMD3 to the N memory banks BK0, BK1, BK2 and BK3 through the M*N independent command lines RCL0, RCL1, RCL2, RCL3, CCL0, CCL1, CCL2 and CCL3 in the normal mode where interference caused by the coupling effect is not likely to occur since the N memory banks BK0, BK1, BK2 and BK3 do not perform the row operation or the column operation at the same time.

In the aforementioned structure of the semiconductor memory device, the test mode may include a compression test mode. Also, the test command ROW_CMD1 may be an active command. Thus, the N memory banks BK0, BK1, BK2 and BK3 are simultaneously enabled in a compression test mode.

In accordance with the second embodiment, as described above, the common command line CMD_JOIN_LINE capable of transmitting a predetermined command, e.g., the command ROW_CMD1 as the common command JOIN_CMD to the N memory banks BK0, BK1, BK2 and BK3 in the test mode, is additionally provided so that the predetermined commands ROW_CMD1 serving as the common command JOIN_CMD may be simultaneously transmitted to all of the N memory banks BK0, BK1, BK2 and BK3 in the test mode in order to simultaneously operate the N memory banks BK0, BK1, BK2 and BK3 included in the semiconductor device.

Therefore, the interference due to the coupling effect between the M*N independent command lines RCL0, RCL1, RCL2, RCL3, CCL0, CCL1, CCL2 and CCL3 may be prevented from occurring in the test mode since the predetermined command ROW_CMD1 serving as the common command JOIN_CMD is simultaneously transmitted to the N memory banks BK0, BK1, BK2 and BK3 through the common command line CMD_JOIN_LINE, instead of transmitting the predetermined commands ROW_CMD1 serving as the common command JOIN_CMD to the N memory banks BK0 BK1, BK2 and BK3 through the M*N independent command lines RCL0, RCL1, RCL2, RCL3, CCL0, CCL1, CCL2 and CCL3 (which respectively transmit the command ROW_CMD0, ROW_CMD1, ROW_CMD2, ROW_CMD3, COLUMN_CMD0, COLUMN_CMD1, COLUMN_CMD2 or COLUMN_CMD3 to the N memory banks BK0, BK1, BK2 and BK3) in the test mode.

Also, current consumption may greatly decrease compared with the case where the predetermined commands ROW_CMD1 serving as the common command JOIN_CMD are simultaneously transmitted to the N memory banks BK0, BK1, BK2 and BK3 through the M*N independent command lines RCL0, RCL1, RCL2, RCL3, CCL0, CCL1, CCL2 and CCL3.

In accordance with embodiments, a common transmission line that may transmit a common command to a plurality of internal circuits is additionally provided in a predetermined operation mode where the internal circuits simultaneously perform a predetermined operation so that the predetermined command may be simultaneously transmitted to the plurality of internal circuits.

Since the predetermined command is simultaneously transmitted to the internal circuits through the common transmission line instead of through a plurality of command transmission lines, interference due to a coupling effect between the plurality of command transmission lines that re adjacent each other may be prevented.

Also, current consumption may greatly decrease compared with when a predetermined command is simultaneously transmitted to the internal circuits through a plurality of command transmission lines.

The embodiments described above should not be construed restrictive or limitative.

What is claimed is:

1. A semiconductor device, comprising:
a plurality of internal circuits which receive commands through a plurality of independent command lines in a first operation mode and receive a common command through a common command line in a second operation mode; and
an operation control block which duplicates a command applied through a representative independent command line, which is selected among the plurality of independent command lines, in the second operation mode and transmits the duplicated command as the common command to the common command line.

2. The semiconductor device of claim 1, further comprising:
a command generation block which generates a first operation command in the first operation mode and outputs the first operation command to one or more of the plurality of independent command lines in response to a circuit selection signal, and generates a second operation command in the second operation mode and outputs the second operation command to the representative independent command line.

3. The semiconductor device of claim 2, wherein the operation control block couples the representative independent command line with the common command line in the second operation mode and disconnects the representative independent command line from the common command line in the first operation mode.

4. The semiconductor device of claim 3, wherein the plurality of internal circuits are coupled with the plurality of independent command lines and are disconnected from the common command line in the first operation mode, and the plurality of internal circuits disconnected from the plurality of independent command lines are commonly coupled with the common command line in the second operation mode.

5. The semiconductor device of claim 2, wherein the plurality of internal circuits, upon receiving the second operation command in the second operation mode, simultaneously perform a predetermined second operation.

6. The semiconductor device of claim 5, wherein one or more of the plurality of internal circuits, to which the first operation command is transmitted in response to the circuit selection signal in the first operation mode, independently perform a predetermined first operation.

7. A semiconductor memory device, comprising:
N memory banks which receive M commands through M*N independent command lines in a normal mode and receive a common command through a common command line in a test mode, wherein M and N are integers, N is a total number of memory banks, and M is a total number of operations performed by the N memory banks; and
an operation control block which duplicates a command applied through a representative independent command line, which is selected among the M*N independent command lines, in the test mode and transmits the duplicated command as the common command to the common command line.

8. The semiconductor memory device of claim 7, further comprising:
a command generation block which generates a normal command in the normal mode and outputs the normal command to one or more of the M*N independent command lines in response to a bank address, and generates a test command in the test mode and outputs the test command to the representative independent command line.

9. The semiconductor memory device of claim 8, wherein the operation control block couples the representative independent command line with the common command line in the test mode, and disconnects the representative independent command line from the common command line in the normal mode.

10. The semiconductor memory device of claim 9, wherein the N memory banks are coupled with the M*N independent command lines and are disconnected from the common command line in the normal mode, and
wherein the N memory banks are disconnected from the M*N independent command lines and are commonly coupled with the common command line in the test mode.

11. The semiconductor memory device of claim 8, wherein the N memory banks, which commonly share the test command in the test mode, simultaneously perform a predetermined test operation.

12. The semiconductor memory device of claim 11, wherein one or more of the N memory banks, to which the normal command is transmitted in response to the bank address in the normal mode, independently perform a predetermined normal operation.

13. The semiconductor memory device of claim 11, wherein the test mode is a compression test mode, the test command is an active command, and the N memory banks are simultaneously enabled in the predetermined test operation.

14. A semiconductor device, comprising:
a command generation block suitable for being coupled to a first or a second memory circuit in a first operation mode and further suitable for being disconnected from both of the first and the second memory circuits in a second operation mode, and
an operation control block suitable for being disconnected from both of the first and the second memory circuits in the first operation mode and further suitable for being commonly coupled to both of the first and the second memory circuits in the second operation mode.

15. The semiconductor device of claim 14,
wherein, in the first operation mode, the command generation block generates a first command signal in response to an input command signal, selects a memory circuit between the first and the second memory circuits in response to a circuit selection signal, and transmits the first command signal to the selected memory circuit.

16. The semiconductor device of claim 15,
wherein, upon receiving the first command signal, the selected memory circuit performs a first operation, and
wherein the first operation includes an active operation, a precharge operation, a read operation, a write operation, or a combination thereof.

17. The semiconductor device of claim 14,
wherein, in the second operation mode, the operation control block receives a second command signal and transmits the second command signal to both of the first and the second memory circuits.

18. The semiconductor device of claim 17,
wherein, upon receiving the second command signal, both of the first and second memory circuits perform the second operation, and
wherein the second operation includes an active operation, a precharge operation, a read operation, a write operation, or a combination thereof.

19. The semiconductor device of claim 14,
wherein the second operation mode is a test mode.

20. The semiconductor device of claim 14, further comprising third and fourth memory circuits,
wherein the command generation block is suitable for being coupled to the first, the second, the third, or the fourth memory circuit in the first operation mode and further suitable for being disconnected from all of the first through the fourth memory circuits in the second operation mode, and
wherein the operation control block is suitable for being disconnected from all of the first through the fourth memory circuits in the first operation mode and further suitable for being commonly coupled to two or more of the first through the fourth memory circuits in the second operation mode.
